(19) United States
(12) Patent Application Publication
(10) Pub. No.: US 2019/0259806 A1
(43) Pub. Date: Aug. 22, 2019

(54) SURFACE ACOUSTIC WAVE RESONATOR STRUCTURE

(71) Applicant: Intel Corporation, Santa Clara, CA (US)

(72) Inventors: Paul FISCHER, Portland, OR (US); Sansaptak DASGUPTA, Hillsboro, OR (US); Marko RADOSAVLJEVIC, Portland, OR (US); Han Wui THEN, Portland, OR (US); Edris MOHAMMED, Beaverton, OR (US)

(21) Appl. No.: 16/347,724

(22) PCT Filed: Dec. 28, 2016
(86) PCT No.: PCT/US2016/068992

§ 371 Date: May 6, 2019

(51) Int. Cl. H01L 27/20; H03H 3/08; H03H 9/02; H03H 9/10; H03H 9/145; H03H 9/25

(52) U.S. Cl. CPC H01L 27/20; H03H 3/08; H03H 9/25; H03H 9/1092; H03H 9/145; H03H 9/02543

(57) ABSTRACT

A surface acoustic wave (SAW) resonator structure, an integrated circuit, and a method of fabricating a SAW structure are provided. The method includes epitaxially growing a crystalline aluminum nitride piezoelectric film layer on a substrate; and deposing a plurality of electrodes on the piezoelectric film layer. The SAW structure includes a substrate, a piezoelectric film on the substrate, and a plurality of electrodes on the piezoelectric film.

### FIELD

The present disclosure generally relates to surface acoustic wave (SAW) resonators integrated in a radio frequency (RF) front end.

### BACKGROUND

Modern RF front ends feature acoustic filters. An acoustic filter is a circuit that includes at least (and typically significantly more) two resonators. In such filters, SAW devices may be implemented. SAW devices may be fabricated directly on an integrated circuit (IC) die cut from a single crystal lithium niobate (LiNBO3), or other suitable piezoelectric crystal, wafer. However, SAW devices are often implemented in structures that may be monolithically integrated onto a substrate common to other active circuit devices to enable higher system performance and scaling. In such instances, monolithically integrated SAW resonator devices are comprised of sputtered aluminum nitride (AlN) films, in which the sputtered AlN has a vertical crystallographic axis (c-axis) that is perpendicular to the substrate surface. However, such SAW devices couple primarily to in-plane coupling coefficients, which are less effective and result in lower bandwidth and quality factor.

### BRIEF DESCRIPTION OF THE DRAWINGS

FIG. 1 illustrates one embodiment of a SAW resonator structure.

FIG. 2 is a flow diagram illustrating one embodiment of a process for fabricating a SAW resonator structure.

FIGS. 3A-3F illustrate embodiments of a SAW resonator structure during fabrication.

FIGS. 4A & 4B illustrate embodiments of plane orientations of a SAW resonator structure.

FIG. 5 illustrates a system in which an acoustic resonator structure may be implemented.

### DETAILED DESCRIPTION

In the following description, numerous specific details are set forth in order to provide a thorough understanding of various embodiments. However, various embodiments of the invention may be practiced without the specific details. In other instances, well-known methods, procedures, components, and circuits have not been described in detail so as not to obscure the particular embodiments of the invention.

According to one embodiment, a monolithically integrated surface acoustic wave (SAW) resonator structure is disclosed. The SAW structure includes a substrate, a piezoelectric film comprised of aluminum nitride (AlN) epitaxially grown on the substrate and layer a plurality of electrodes deposited on the piezoelectric film. In a further embodiment, the SAW structure includes a c-axis that is parallel to the substrate to provide vertical resonators, which enables a high coupling coefficient parallel to a substrate surface.

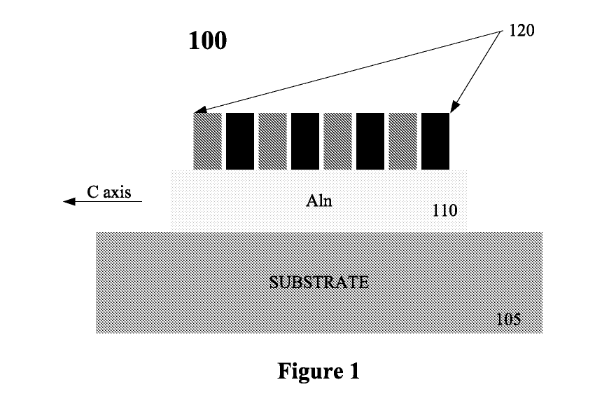

FIG. 1 illustrates one embodiment of a SAW resonator structure 100. Resonator structure 100 includes an AlN piezoelectric film layer 110 deposited on a substrate 105. According to one embodiment, substrate 105 is comprised of silicon (Si). However, substrate 105 may be comprised of other materials (e.g., silicon dioxide (Si02), aluminum oxide (Al2O3), germanium, etc.). Additionally, electrodes 120 are deposited on AlN piezoelectric film layer 110. In one embodiment, piezoelectric film layer 110 is deposited via epitaxial growth, which enables fine control of the piezoelectric film layer 110 thickness.

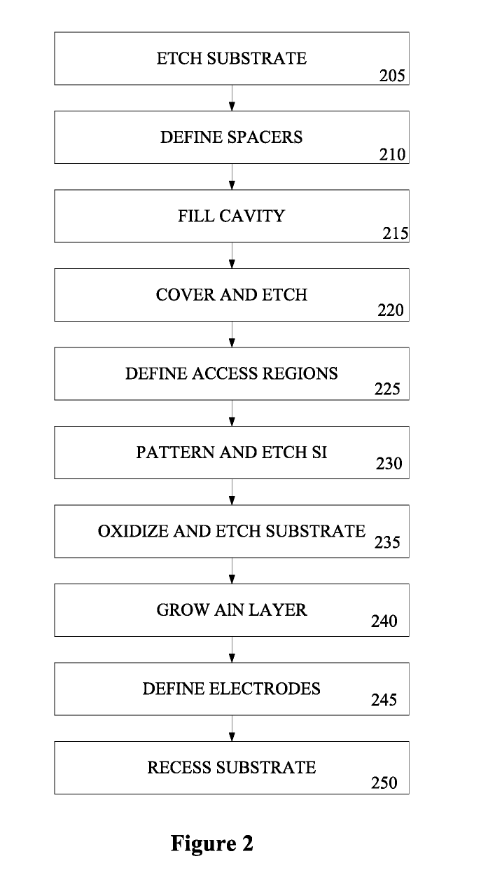

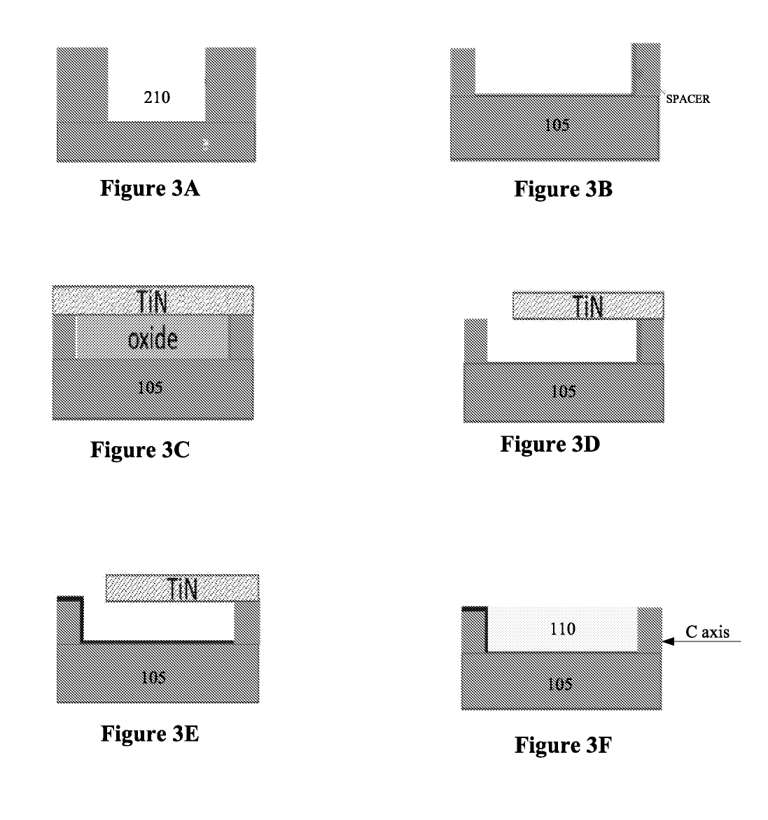

FIG. 2 is a flow diagram illustrating one embodiment of a process for fabricating a resonator structure 100. At processing block 205, a vertical cavity (or trench) is patterned into substrate 105. In one embodiment, a crystallographic wet etch of the Si substrate is implemented to create atomically smooth substrate 105 planes with the (110) or (111) surface planes. In such an embodiment, the planes are sufficiently close to the AlN layer 110 lattice constant to enable high quality growth. FIG. 3A illustrates one embodiment of resonator structure 100 after a trench has been etched into substrate 105.

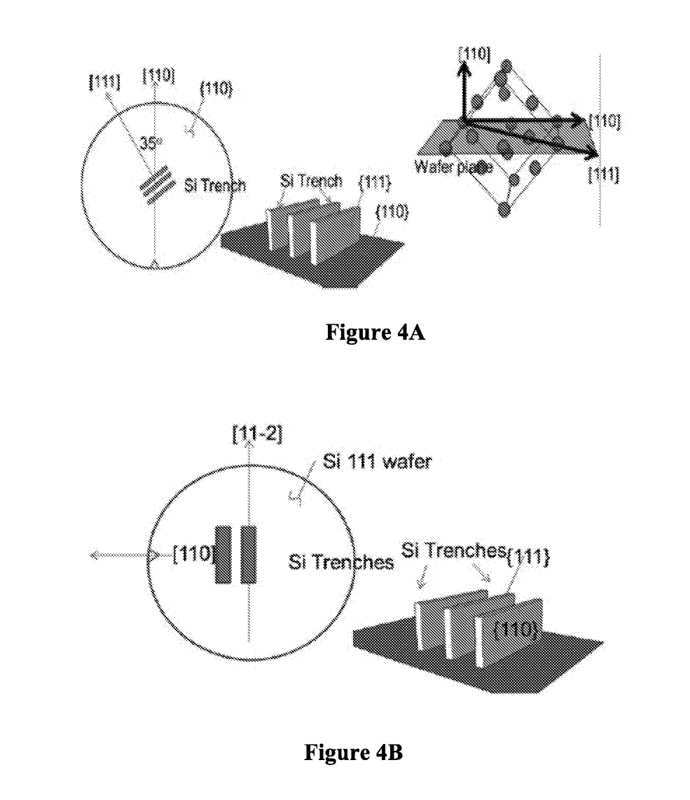

In one embodiment, the etching process begins with lithographically printing an etch mask layer. Subsequently, bulk etching of Si may be accomplished via Reactive-ion etching (RIE) techniques. However, the final etch may be performed with a potassium hydroxide (KOH) wet etch to select specific crystal planes with low etch rates (e.g., a {111} plane orientations) on a {110} Si wafer. Specific planes can be selected by aligning a trench pattern on the substrate. A similar technique may be used to preferentially stop on a {110} plane orientation assuming a {111} Si wafer is used. A mechanism based on etch rates of Si in KOH may be {100} plane orientation >{110} plane orientation >{111} plane orientation. FIG. 4A illustrates one embodiment of a {111} plane orientation of a trench wall relative to a (110) plane of the substrate, while FIG. 4B illustrates one embodiment of a {110} plane orientation relative to a (111) plane of the substrate.

At processing block 210, self-aligned spacers are defined on the cavity sidewalls of substrate 105, with unwanted spacers being selected and etched away using photolithography. Thus, spacers remain only where AlN seeding is desired. FIG. 3B illustrates one embodiment of resonator structure 100 after spacers have been defined. At processing block 215, the substrate 105 cavity is filled with an oxide layer, and the overburden is removed via chemical mechanical planarization (CMP). At processing block 220, complimentary film layer is deposited to cover the oxide layer and substrate sidewalls. Subsequently, the complimentary film is selectively etched relative to the oxide and substrate material (e.g., Si). In one embodiment, titanium nitride (TiN) is implemented for the film. However, other embodiments materials, such as [tungsten (W), tanatalum (Ta), tanatalum nitride (TaN), etc., may be implemented. FIG. 3C illustrates one embodiment of resonator structure 100 after the cavity is filled with oxide and covered with the complimentary film.

At processing block 225, access regions between the complimentary film and the cavity fill material are defined using lithography and etching. At processing block 230, the oxide fill is etched away. FIG. 3D illustrates one embodiment of resonator structure 100 after the oxide fill layer has been etched. At processing block 235, substrate 105 is oxidized and a spacer etch is performed. FIG. 3E illustrates one embodiment of resonator structure 100 after substrate 100 has been oxidized and etched. At processing block 240, the AlN layer 100 is grown on substrate 105. In one embodiment, AlN layer 110 is epitaxially grown with the onset of growth occurring off of the substrate 105 sidewall. FIG. 3F illustrates one embodiment of resonator structure 100 after AlN layer 100 is grown on substrate 105.

At processing block 245, the electrodes 120 metal are defined. In one embodiment, the electrodes are defined using a damascene etch process. However in other embodiments, the electrodes may be defined using a subtractive etch process. In a further embodiment, the electrode metal may comprise Al, W, platinum (Pt) or any other suitable conductor. At processing block 250, the substrate 105 material adjacent to piezoelectric AlN 110 is recessed. The structure 100 of FIG. 1 is the result once the process has been completed. According to one embodiment, additional layers may be added to resonator structure 100. In such an embodiment, resonator structure 100 may be sealed (e.g., via breadloafing of chemical vapor deposition (CVD) films or bonding of a cap) to enable vias and additional fabrication to be performed using known technique.

As discussed above, a SAW structure includes a piezoelectric film comprised of aluminum nitride (AlN) epitaxially grown on the substrate to provide for high quality. Additionally, the SAW structure includes a c-axis that is parallel to the electrodes and the substrate surface. Such a configuration enables the structure to couple into enhanced material properties.

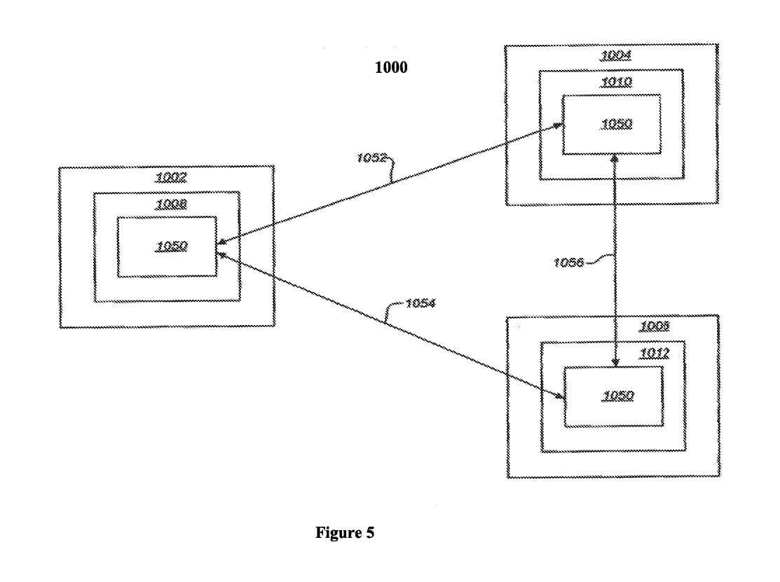

FIG. 5 illustrates one embodiment of a computer system 1000 in which an acoustic resonator may be implemented. System 1000 may comprise, for example, a communication system having multiple nodes. A node may comprise any physical or logical entity having a unique address in system 1000. Examples of a node may include, but are not necessarily limited to, a computer, server, workstation, laptop, ultra-laptop, handheld computer, telephone, cellular telephone, personal digital assistant (PDA), router, switch, bridge, hub, gateway, wireless access point (WAP), and so forth. The unique address may comprise, for example, a network address such as an Internet Protocol (IP) address, a device address such as a Media Access Control (MAC) address, and so forth. The embodiments are not limited in this context.

The nodes of system 1000 may be arranged to communicate different types of information, such as media information and control information. Media information may refer to any data representing content meant for a user, such as voice information, video information, audio information, text information, alphanumeric symbols, graphics, images, and so forth. Control information may refer to any data representing commands, instructions or control words meant for an automated system. For example, control information may be used to route media information through a system, or instruct a node to process the media information in a predetermined manner.

The nodes of system 1000 may communicate media and control information in accordance with one or more protocols. A protocol may comprise a set of predefined rules or instructions to control how the nodes communicate information between each other. The protocol may be defined by one or more protocol standards as promulgated by a standards organization, such as the Internet Engineering Task Force (IETF), International Telecommunications Union (ITU), the Institute of Electrical and Electronics Engineers (IEEE), the 3rd Generation Partnership Project (3GPP), 5th generation mobile networks (5G), and so forth.

System 1000 may be implemented as a wireless communication system and may include one or more wireless nodes arranged to communicate information over one or more types of wireless communication media. An example of a wireless communication media may include portions of a wireless spectrum, such as the radio-frequency (RF) spectrum or frequency spectrum in the millimeter wave range (30-300 GHz). Carrier frequencies used in the system may include frequencies between 24.25 GHz till 27 GHz, or include/contain frequencies at 27.5, 28, 29, 30, 31, 37.5, 38, 39, 40, 41, 50, 66, 71, 76, 81, 86 GHz or frequencies above 86 GHz. The wireless nodes may include components and interfaces suitable for communicating information signals over the designated wireless spectrum, such as one or more antennas, wireless transmitters/receivers (“transceivers”), amplifiers, filters, control logic, and so forth. Examples for the antenna may include an internal antenna, an omni-directional antenna, a monopole antenna, a dipole antenna, an end fed antenna, a circularly polarized antenna, a micro-strip antenna, a micro-strip patch antenna, an endfire antenna, a diversity antenna, a dual antenna, an antenna array for beamforming reasons or electronic beam steering functionality, and so forth.

Referring again to FIG. 5, system 1000 may comprise node 1002, 1004, and 1006 to form a wireless communication network, such as, a PAN, for example. Although FIG. 5 is shown with a limited number of nodes in a certain topology, it may be appreciated that system 1000 may include more or less nodes in any type of topology as desired for a given implementation. The embodiments are not limited in this context.

In one embodiment, system 1000 may comprise node 1002, 1004, and 1006 each may comprise a transceiver 1008, 1010, and 1012, respectively, and a CMOS integrated circuit device 1050. The CMOS integrated circuit device 1050 may comprise any one of antenna systems to form a wireless communication network through wireless links 1052, 1054, 1056, for example. In some embodiment, the CMOS integrated circuit device 1050 may be replaced by other semiconductor technology as (silicon) CMOS. The CMOS integrated circuit device 1050 maybe integrated within a system in package (SIP), which comprises any one of antenna systems to form a wireless communication or sensor network through wireless links 1052, 1054, 1056.

The embodiments are not limited to planar bulk silicon CMOS integration but can include usage of semiconductor/silicon on insulator (SOI) technology. The resonator structure could be used not only in silicon CMOS technology but also be integrated within Bipolar or BiCMOS technologies. Semiconductor materials can include any one of, silicon, germanium, silicon-germanium (SiGe), GaAs, InAs, GaN, InN, AlN, InSb, InP. The embodiments are not limited to the integration within semiconductor technologies but could be realized also in package technologies (e.g. wafer level bonding technologies, etc.)

References to “one embodiment”, “an embodiment”, “example embodiment”, “various embodiments”, etc., indicate that the embodiment(s) so described may include particular features, structures, or characteristics, but not every embodiment necessarily includes the particular features, structures, or characteristics. Further, some embodiments may have some, all, or none of the features described for other embodiments.

In the following description and claims, the term “coupled” along with its derivatives, may be used. “Coupled” is used to indicate that two or more elements co-operate or interact with each other, but they may or may not have intervening physical or electrical components between them.

As used in the claims, unless otherwise specified the use of the ordinal adjectives “first”, “second”, “third”, etc., to describe a common element, merely indicate that different instances of like elements are being referred to, and are not intended to imply that the elements so described must be in a given sequence, either temporally, spatially, in ranking, or in any other manner.

The following clauses and/or examples pertain to further embodiments or examples. Specifics in the examples may be used anywhere in one or more embodiments. The various features of the different embodiments or examples may be variously combined with some features included and others excluded to suit a variety of different applications. Examples may include subject matter such as a method, means for performing acts of the method, at least one machine-readable medium including instructions that, when performed by a machine cause the machine to performs acts of the method, or of an apparatus or system for facilitating hybrid communication according to embodiments and examples described herein.

Some embodiments pertain to Example 1 that includes a method of fabricating a surface acoustic wave (SAW) structure, comprising epitaxially growing a crystalline aluminum nitride (AlN) piezoelectric film layer on a substrate and depositing a plurality of electrodes on the piezoelectric film layer.

Example 2 includes the subject matter of Example 1, wherein the piezoelectric film layer has a crystallographic axis (c-axis) that is parallel to a surface of the substrate.

Example 3 includes the subject matter of Examples 1 and 2, wherein fabricating the SAW structure further comprises creating a vertical cavity in a substrate.

Example 4 includes the subject matter of Examples 1-3, wherein creating the cavity in the substrate comprises performing a crystallographic wet etch on the substrate.

Example 5 includes the subject matter of Examples 1-4, wherein fabricating the SAW structure further comprises, defining self-aligned spacers on the cavity walls of the substrate and selectively etching the spacers.

Example 6 includes the subject matter of Examples 1-5, wherein fabricating the SAW structure further comprises filling the vertical cavity with an oxide layer and depositing a complimentary film layer to cover the oxide and the cavity walls of the substrate.

Example 7 includes the subject matter of Examples 1-6, wherein the complimentary film layer comprises titanium nitride.

Example 8 includes the subject matter of Examples 1-7, wherein fabricating the SAW structure further comprises selectively etching the complimentary film relative to the oxide and substrate material.

Example 9 includes the subject matter of Examples 1-8, wherein fabricating the SAW structure further comprises defining an access region between the complimentary film and substrate; and etching the oxide layer.

Example 10 includes the subject matter of Examples 1-9, wherein fabricating the SAW structure further comprises oxidizing the substrate and performing a spacer etch.

Example 11 includes the subject matter of Examples 1-10, wherein fabricating the SAW structure further comprises epitaxially growing the crystalline AlN piezoelectric film layer in the substrate cavity.

Example 12 includes the subject matter of Examples 1-11, further comprising depositing a sealing layer over the plurality of electrodes.

Some embodiments pertain to Example 13 that includes a surface acoustic wave (SAW) structure comprising a substrate, a piezoelectric film epitaxially grown on the substrate and a plurality of electrodes deposited on the piezoelectric film.

Example 14 includes the subject matter of Example 13, wherein the piezoelectric film comprises an aluminum nitride (AlN) layer epitaxially grown on the substrate.

Example 15 includes the subject matter of Examples 13 and 14, wherein the piezoelectric film layer has a crystallographic axis (c-axis) that is parallel to a surface of the substrate.

Example 16 includes the subject matter of Examples 13-15, further comprising a sealing layer deposited over the plurality of electrodes.

Some embodiments pertain to Example 17 that includes an integrated circuit (IC) comprising one or more surface acoustic wave (SAW) structures, each SAW structure including a substrate, a piezoelectric film epitaxially grown on the substrate and a plurality of electrodes deposited on the piezoelectric film.

Example 18 includes the subject matter of Example 17, wherein the piezoelectric film comprises an aluminum nitride (AlN) layer epitaxially grown on the substrate.

Example 19 includes the subject matter of Examples 17 and 18 wherein the piezoelectric film layer has a crystallographic axis (c-axis) that is parallel to a surface of the substrate.

Example 20 includes the subject matter of, Examples 17-19, further comprising a sealing layer deposited over the plurality of electrodes.

Although embodiments of the invention have been described in language specific to structural features and/or methodological acts, it is to be understood that claimed subject matter may not be limited to the specific features or acts described. Rather, the specific features and acts are disclosed as sample forms of implementing the claimed subject matter.

1.-20. (canceled)

21. A method of fabricating a surface acoustic wave (SAW) structure, comprising:
epitaxially growing a crystalline aluminum nitride (AlN) piezoelectric film layer on a substrate; and
depositing a plurality of electrodes on the piezoelectric film layer.

22. The method of claim 21, wherein the piezoelectric film layer has a crystallographic axis (c-axis) that is parallel to a surface of the substrate.

23. The method of claim 21, wherein fabricating the SAW structure further comprises creating a vertical cavity in a substrate.

24. The method of claim 23, wherein creating the cavity in the substrate comprises performing a crystallographic wet etch on the substrate.

25. The method of claim 23, wherein fabricating the SAW structure further comprises:
defining self-aligned spacers on the cavity walls of the substrate; and
selectively etching the spacers.

26. The method of claim 25, wherein fabricating the SAW structure further comprises:
filling the vertical cavity with an oxide layer; and
depositing a complimentary film layer to cover the oxide and the cavity walls of the substrate.

27. The method of claim 26, wherein the complimentary film layer comprises titanium nitride.

28. The method of claim 26, wherein fabricating the SAW structure further comprises selectively etching the complimentary film relative to the oxide and substrate material.

29. The method of claim 26, wherein fabricating the SAW structure further comprises:
defining an access region between the complimentary film and substrate; and
etching the oxide layer.

30. The method of claim 29, wherein fabricating the SAW structure further comprises:
oxidizing the substrate; and
performing a spacer etch.

31. The method of claim 30, wherein fabricating the SAW structure further comprises epitaxially growing the crystalline AlN piezoelectric film layer in the substrate cavity.

32. The method of claim 31, further comprising depositing a sealing layer over the plurality of electrodes.

33. Surface acoustic wave (SAW) structure comprising:
a substrate;
a piezoelectric film epitaxially grown on the substrate; and
a plurality of electrodes deposited on the piezoelectric film.

34. The SAW structure of claim 33, wherein the piezoelectric film comprises an aluminum nitride (AlN) layer epitaxially grown on the substrate.

35. The SAW structure of claim 34, wherein the piezoelectric film layer has a crystallographic axis (c-axis) that is parallel to a surface of the substrate.

36. The SAW structure of claim 33, further comprising a sealing layer deposited over the plurality of electrodes.

37. An integrated circuit (IC) comprising one or more surface acoustic wave (SAW) structures, each SAW structure including:
a substrate;
a piezoelectric film epitaxially grown on the substrate; and
a plurality of electrodes deposited on the piezoelectric film.

38. The IC of claim 37, wherein the piezoelectric film comprises an aluminum nitride (AlN) layer epitaxially grown on the substrate.

39. The IC of claim 37, wherein the piezoelectric film layer has a crystallographic axis (c-axis) that is parallel to a surface of the substrate.

40. The IC of claim 39, further comprising a sealing layer deposited over the plurality of electrodes.
